(19) United States
(12) Patent Application Publication
(10) Pub. No.: US 2009/0115451 A1
(43) Pub. Date: May 7, 2009

(54) CONFIGURABLE AND REUSABLE NAND SYSTEM

(76) Inventors: Sandeep BRAHMADATHAN, Trichur (IN); Bikram BANERJEE, Jadavour (IN)

Correspondence Address: EVERGREEN VALLEY LAW GROUP, 2670 S. WHITE ROAD, SUITE 275, SAN JOSE, CA, 95148, US

(21) Appl. No.: 11/934,790

(22) Filed: Nov. 5, 2007

(51) Int. Cl. H03M 13/37

(52) U.S. Cl. 326/38; 714/819; 714/E11.002

(57) ABSTRACT

A configurable and reusable hardware-software NAND system adaptive to various NAND devices independent of the NAND device manufacturer and NAND device characteristics. A device identification signature is decoded from a NAND device in a NAND system; the device identification signature signal is analyzed to obtain a control phase sequence value descriptive of a characteristic of the NAND device; the control phase register is populated with the control phase sequence value; and control phase register provides the control phase sequence values to the command sequencer. The control phase register can be programmed by a low level driver for devices which NAND system cannot decode the device identification signature.

### BACKGROUND

Embodiments of the invention relate generally to NAND devices and more particularly to a configurable and reusable NAND system.

A NAND device includes a plurality of blocks, each of which has a predetermined size for preserving data similar to a cluster of a hard disk. A Read/write operation to a NAND device is performed with a block and a page as a processed unit. An I/O (Input/Output) port with, for example, 8 bits may be used on a NAND device. A NAND device accesses data in sequence and the access mode is in a serial fashion. A NAND system provides interaction capabilities between a NAND device and a processor.

Deploying NAND systems in today's System on Chip (SoC) designs requires highly integrated solutions to address issues of data integrity and system performance. FIG. 1 illustrates a simplified block diagram of a NAND system 115 according to the prior art. The NAND system 115 includes a NAND Flash File System (FFS) 105, a Low-Level Driver (LLD) 110 coupled to the NAND FFS 105 and a NAND controller 120 in communication with the LLD 110. The NAND FFS 105 provides unique functionalities required for NAND device interface. The NAND controller 120 can be programmed to interact with a NAND device 125 coupled to the NAND system 115. Once integrated into a NAND platform, the usability and life of the NAND system 115 will depend on the ability of that NAND system to interact with a myriad of NAND devices from different vendors present today and in the future.

Although the above goal of maximizing the usability of NAND systems with different NAND devices seems to be straightforward, immense complexity arises from the fact that NAND devices from different vendors, and different NAND devices from the same vendor, are inherently different in their command sets and command sequences. The value of a NAND system increases with the number of different NAND devices with which the hardware and software components of that NAND system can interact. Once the NAND controller is fixed in silicon and on a NAND platform, it will only be able to interact with NAND devices described in a lookup table incorporated into the NAND controller. In the existing NAND system, if a new NAND device that the NAND controller is not aware of is coupled to the NAND system, the NAND controller will fail to interact with that NAND device.

Thus, an important challenge of designing a NAND system lies in its adaptability to the devices of the present and of the future. Intelligence of how to interact with present NAND devices can be built into the system. What is needed is a NAND system adaptable to future NAND devices, which could be different from all existing NAND devices in command set and command sequencing.

### SUMMARY

Embodiments of the invention described herein provide a method and system for a configurable and reusable NAND system which is adaptive to various NAND devices independent of the NAND device manufacturer and NAND device characteristics.

An exemplary embodiment of the invention provides a method for configuring a NAND system when coupled with a NAND device. The method decodes a device identification signature signal from at least one NAND; analyzes the device identification signature signal to obtain control phase sequence values descriptive of the characteristic of the NAND device; populates the control phase registers with the control phase sequence values; and control phase registers then provide the stored control phase sequence values to the command sequencer.

An exemplary embodiment of the invention provides a system for configuring a NAND system when coupled with the NAND device. The system includes an initialization engine for capturing device identification signature signal of a NAND device; a command sequencer that interacts with the NAND device; a set of control phase registers that stores control phase sequence values corresponding to device identification signature signal and provides control phase sequence values to the command sequencer; and a low level driver for providing an initialization sequence comprising a set of control phase sequence values to the control phase registers.

Other aspects and example embodiments are provided in the Figures and the Detailed Description that follows.

### BRIEF DESCRIPTION OF THE DRAWINGS

FIG. 1 illustrates a simplified block diagram of a NAND system according to the prior art;

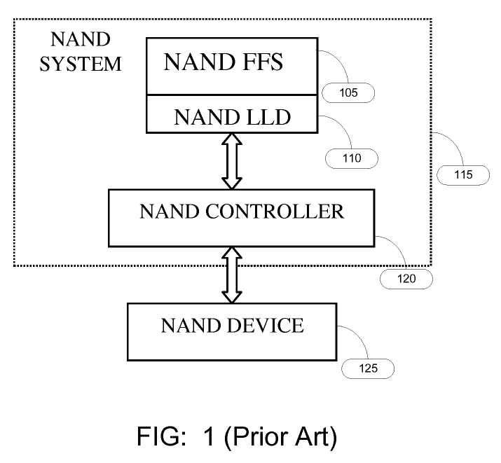

FIG. 2 is a flow diagram illustrating a method for configuring a NAND system according to an embodiment of the invention; and

FIG. 3 is a block diagram illustrating an exemplary implementation of a reconfigurable NAND system according to an embodiment of the invention.

### DETAILED DESCRIPTION OF THE EMBODIMENTS

Embodiments of the invention described herein provide a method and system for a configurable and reusable hardware-software NAND system which is adaptive to various NAND devices independent of the NAND device manufacturer and NAND device characteristics.

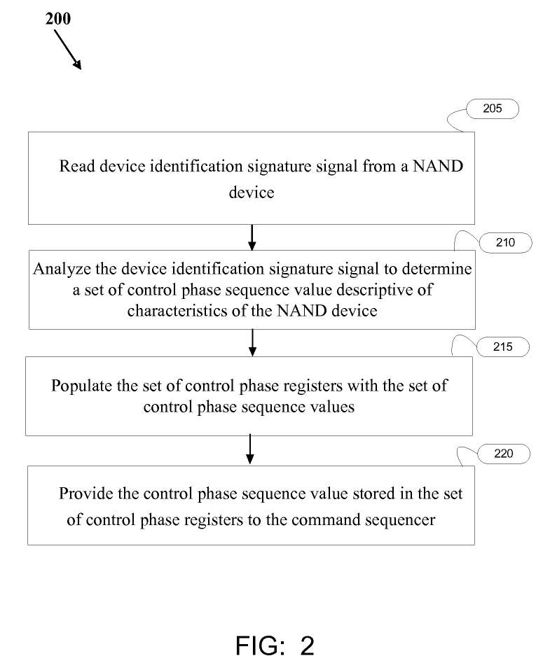

FIG. 2 is a flow diagram 200 illustrating the steps in the method for configuring a NAND device coupled to a NAND system according to an embodiment of the invention. In one embodiment of the invention, the NAND device includes a new NAND device that has not been previously coupled to the NAND system, or information of that NAND device does not exist in the lookup table of the NAND controller which is hereinafter referred to as a new NAND device'.

If a particular NAND device's information which is coupled to a NAND system is not present in a lookup table, the lookup table fails to decode the correct device identification signature signals and instead provides a default set of signals to the control phase registers. When the lookup table fails to decode the correct device identification signature signals for the control phase registers, the method of the embodiment of the invention configures the NAND controller to interact with the NAND device using steps 205-220. In short, steps 205-220 override the control phase registers with the control phase sequence values that are required for the NAND controller to interact with the new NAND device.

In step 205, the Low Level Driver (LLD) of the software reads the device identification signature from the NAND controller. In step 210, LLD analyzes the device signature identification signal to determine a set of control phase sequence values descriptive of the characteristics of the NAND device and thereby captures the NAND device's information that needs to be populated in the set of control phase registers. Upon analyzing the NAND device's information, the control phase registers are populated with the above-determined control phase sequence values using the NAND controller in step 215. In step 220, the control phase sequence values stored in the control phase registers are provided to the command sequencer for the NAND system to interact with the NAND device. The control phase sequence values include command phase sequence values and data phase sequence values which are derived from the device identification values.

In one embodiment of the invention, for populating the control phase registers with a set of control phase sequence values in case of a new NAND device, device signature information of the new NAND device is captured from a manufacturer ID, NAND device ID, page size information and device size information. Upon capturing the device signature information, the control phase registers are populated with the control phase sequence values of the new NAND device using the LLD.

In one embodiment of the invention, a set of abstracted control phase registers is populated with the control phase sequence values representing the device characteristics, and an initialization sequence is provided from the LLD to populate the abstracted control phase registers in case of a new NAND device. The abstracted control phase registers contain device signature information, which is decoded to populate the control phase registers with control phase sequence values characteristic to the NAND device. The control phase registers then provide the control phase sequence values to the command sequencer to interact with the NAND device.

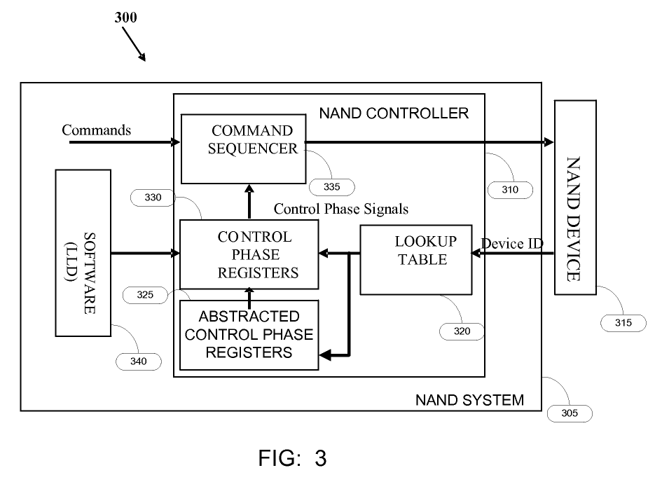

FIG. 3 is a block diagram 300 illustrating an exemplary implementation of a configurable NAND system embodying the principles of the invention. The block diagram 300 includes a NAND device 315 coupled to a NAND system 305. The NAND system 305 includes a NAND controller 310 coupled to a Low Level Driver (LLD) 340. The NAND controller 310 further includes a lookup table 320, a command sequencer 335, a set of control phase registers 330 and an abstracted control phase register 325 coupled to each other.

The command sequencer 335, which is programmable, generates different command sets and command sequences. Depending on the type of NAND device 315 coupled to the NAND controller 310, the command sequencer 335 in the NAND controller 310 can be programmed to interact with that NAND device 315. Command sequencer 335 may be programmed through a set of unique device identification signature signals, which guide the command sequencer 335 through different command/address/data phases on the NAND device 315 interfaces. A device identification signature signal exists for every command type that the NAND device 315 supports.

At power-on of the NAND system 305, the NAND controller 310 reads the device ID of the NAND device 315 coupled to the NAND system 305. The NAND controller 310 further includes a lookup table 320 which includes information of all known NAND devices existing at the time of a particular NAND controller 310 release. If the read NAND device ID matches a known device ID, NAND controller 310 auto configures itself to work with that NAND device 315. After the device ID is decoded, the NAND controller 310 decodes values of the device identification signature signals to be applied to the control phase register set 330 from the lookup table 320. As in the prior art, this method works for all devices existing at the time of NAND controller 310 release.

As discussed in FIG. 2, 200 if the NAND controller 310 detects a NAND device 315 which does not exist in the lookup table 320, the lookup table 320 fails to decode the correct device identification signature signal and instead provides a default signal to the control phase register set 330. The NAND controller 310 is not functional when the default signal is provided to the command sequencer 335. One embodiment of the invention uses the LLD 340 of the software to read the NAND device ID via a controller register (not shown in FIG. 3) and allows the LLD 340 to provide the correct control phase values to the control phase register set 330. The control phase registers 330 then provides correct control phase information to the command sequencer 335. The LLD 340 upon reading the NAND device ID can judge if the NAND controller 310 is aware of the NAND device 315, and if not, LLD 340 configures the NAND controller 310 for proper operation.

In one embodiment of the invention, to configure the NAND controller 310 for providing the critical command phase signal, the signals from the NAND device 315 are routed to the command sequencer 335 from the control phase register 330. After reading NAND device ID through an initialization engine (not shown in FIG. 4), if the NAND controller 310 detects the NAND device ID is not present in the lookup table 320 as discussed above, NAND controller 310 populates control phase registers 330 with some default values. Later on, the LLD 340 can override the control phase registers 330 with values that it decides are required for the NAND controller 310 to interact with the new NAND device 315.

For a new NAND device 315 that the NAND system 305 needs to support, an initialization sequence for values stored in the abstracted control phase register 325 or control phase registers 330 can be packaged with the LLD 340 of the software. The initialization sequence includes the correct control phase sequence values to be programmed into the abstracted control phase register 325 or control phase register 330 for the NAND controller 310 to interact with the new NAND device 315. As new NAND devices become available, newer initialization sequences can be integrated to the NAND system 305, enhancing its usability and lifetime on the deployed platform.

The forgoing description sets forth numerous specific details to convey a thorough understanding of the invention. However, it will be apparent to one skilled in the art that the invention may be practiced without these specific details. Well-known features are sometimes not described in detail in order to avoid obscuring the invention. Other variations and embodiments are possible in light of above teachings, and it is thus intended that the scope of invention not be limited by this Detailed Description, but only by the following Claims.

What is claimed is:

1. A method comprising:
decoding at least one device identification signature signal from at least one NAND device;
analyzing said at least one device identification signature signal to obtain a control phase sequence value descriptive of a characteristic of said at least one NAND device;
populating at least one control phase register with said control phase sequence value; and
providing the control phase sequence value to a command sequencer from said control phase register to interact with the said NAND device.

2. The method of claim 1, wherein the at least one device identification signature signal is decoded from at least one NAND device to a command sequencer of a NAND controller through at least one control phase register in a NAND system.

3. The method of claim 1, wherein the control phase sequence value comprises a command phase sequence value and a data phase sequence value which are derived from the device identification signature signal.

4. The method of claim 1, wherein analyzing said at least one device identification signature signal comprises capturing device signature information respecting the at least one NAND device and using the captured device signature information to obtain the control phase sequence value.

5. The method of claim 4, wherein said device signature information is captured from at least one of an identification of a manufacturer of the at least one NAND device, an identification of the at least one NAND device, page size information of the at least one NAND device, and device size information of the at least one NAND device.

6. The method of claim 5, wherein the device signature information is captured from all of the listed sources.

7. The method of claim 1 further comprising:
populating an abstracted control phase register with the device signature information which in turn provides control phase sequence values to control phase registers; and
providing an initialization sequence from a low level driver to the control phase register, wherein said initialization sequence comprises control phase sequence values to be programmed to the control phase register for the command sequencer to interact with the at least one NAND device; and
providing an initialization sequence from a low level driver to abstracted control phase registers, wherein said initialization sequence comprises value to be programmed to abstracted phase registers, which in turn will decode and provide control phase sequence values to the control phase registers.

8. The method of claim 1 and further comprising, prior to decoding of device identification signature signal, selecting a NAND device of a type for which the NAND system has not previously been configured, and wherein the at least one NAND device consists of such a NAND device.

9. The method of claim 1 and further comprising, prior to decoding of device identification signature signal, detecting whether a lookup table in the NAND controller includes information descriptive of the at least one NAND device to provide control phase sequence values to be programmed into the control phase registers.

10. The method of claim 6, wherein detecting whether a lookup table includes information comprises detecting a failure in decoding a device identification signature signal corresponding to the at least one NAND device.

11. A NAND system comprising:
an initialization engine for capturing device identification signature signal of at least one NAND device;
a command sequencer that interacts with said at least one NAND device;
a set of control phase registers that stores control phase sequence values corresponding to said device identification signature signal and provides said control phase sequence values to said command sequencer; and
a low level driver for providing an initialization sequence comprising control phase sequence values to said control phase registers.

12. The NAND system of claim 11 further comprising:
an abstracted control phase register for storing device signature information which in turn provides control phase sequence values to control phase registers; and
said low level driver for providing an initialization sequence comprising values to be programmed to said abstracted control phase register.

13. The NAND system of claim 11, wherein the control phase sequence values comprise command phase sequence values and a data phase sequence values which are derived from the device identification signature signal.
